(19) United States
(12) Patent Application Publication
(10) Pub. No.: US 2012/0068911 A1
(43) Pub. Date: Mar. 22, 2012

(54) ANTENNA MODULE WITH ANTENNA SIGNAL INDICATING FUNCTION

(75) Inventor: CHUN-CHUAN CHANG, Keelung City (TW)

(73) Assignee: AUDEN TECHNO CORP.

(21) Appl. No.: 12/885,667

(22) Filed: Sep. 20, 2010

(51) Int. Cl. H01Q 1/00; G01R 29/08

(52) U.S. Cl. 343/894

(57) ABSTRACT

An antenna module with antenna signal indicating function includes a substrate unit, an antenna unit and a light-emitting unit. The antenna unit has an antenna trace fanned on the substrate unit, and the antenna trace has an antenna body having a grounding portion electrically connect with the antenna body and a feeding portion electrically connect with the antenna body for simultaneously receiving RF signals and DC. The light-emitting unit has a light-emitting element electrically connected between the antenna body and the feeding portion, thus the antenna body and the light-emitting element share the grounding portion. When the user turns on the antenna function of the laptop to receive RF signals, the antenna unit and the light-emitting unit can respectively receive RF signals and DC. Hence, users or bystander could easily judge whether the antenna unit is in use according to light or dark of the light-emitting unit.

### BACKGROUND OF THE INVENTION

1. Field of the Invention

The instant disclosure relates to an antenna module, and more particularly, to an antenna module with antenna signal indicating function.

2. Description of Related Art

Internet rapid development has allowed data and information to be rapidly exchanged and accumulated. Great amount of technology and knowledge could be efficiently broadcasted and shared. In recent years, development in wireless networks allows users to retrieve network resources anytime they want. Information has occupied our daily life and work. One feature of wireless network is without cables associated with traditional network infrastructure. Users could connect to a wireless network and retrieve network resources by using electromagnetic waves or infrared signals for transmitting data between network terminals.

In wireless network system architecture, all network servers transmit and receive wireless data signals via an access point to provide network resources and service with wireless communication. Similarly, in order to utilize the resources and services provided by wireless networks, the connecting terminals need to have the ability of transmitting and receiving wireless data signals. Terminals such as desktops or laptops could have wireless network functions by installing wireless network cards.

However, when the user turns on antenna function of a laptop to receive radio frequency signals, the laptop could actively use a reminder module to remind the user that an antenna module of the laptop is in use. In addition, the reminding module is another control circuit and separately installed from the antenna module of the laptop, thus, there will be an extra manufacturing cost of the conventional laptop due to the installation of the independent reminding module.

### SUMMARY OF THE INVENTION

One particular aspect of the instant disclosure provides an antenna module with antenna signal indicating function. The instant disclosure uses at least one light-emitting element integrating with an antenna trace to form the antenna module for simultaneously receiving radio frequency signals and direct current.

In order to achieve the aforementioned advantages, the instant disclosure provides an antenna module with antenna signal indicating function, including: a substrate unit, an antenna unit and a light-emitting unit. The substrate unit has at least one insulating substrate. The antenna unit has at least one antenna trace formed on a surface of the at least one insulating substrate, and the at least one antenna trace has at least one antenna body. A grounding portion electrically connects to the at least one antenna body and a feeding portion electrically connects to the at least one antenna body for simultaneously receiving radio frequency signals and direct current. The light-emitting unit has at least one light-emitting element electrically connecting between the at least one antenna body and the feeding portion, thus, the at least one antenna body and the at least one light-emitting element share the grounding portion.

In order to achieve the aforementioned advantages, the instant disclosure provides an antenna module with antenna signal indicating function, including: a substrate unit, an antenna unit and a light-emitting unit. The substrate unit has at least one insulating substrate. The antenna unit has at least one antenna trace formed on a surface of the at least one insulating substrate, and the at least one antenna trace has at least one antenna body. A grounding portion electrically connected to the at least one antenna body and a feeding portion electrically connects to the at least one antenna body for simultaneously receiving radio frequency signals and direct current. The light-emitting unit has at least one light-emitting element electrically connects between the at least one antenna body and the grounding portion, thus, the at least one antenna body and the at least one light-emitting element share the grounding portion.

Therefore, because the at least one light-emitting element can be integrating with the at least one antenna trace, the antenna module of the instant disclosure can simultaneously receive radio frequency signals and direct current. In other words, the at least one light-emitting element is considered in the antenna layout, thus, the light-emitting element is electrically and disposed on the antenna trace to reduce the manufacturing cost of the antenna module. In addition, in actual use, when the user turns on the antenna function of the laptop for receiving the radio frequency signals, the antenna unit and the light-emitting unit can respectively receive the radio frequency signals and the direct current. Hence, it is easy for the user or bystander to know whether if the antenna unit is in use or not according to the activity of the light-emitting unit.

To further understand the techniques, means and effects the instant disclosure takes for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention that they be used for limiting the instant disclosure.

### BRIEF DESCRIPTION OF THE DRAWINGS

FIG. 1A shows a top schematic view according to the first embodiment of the instant disclosure;

FIG. 1B shows an antenna layout schematic view according to the first embodiment of the instant disclosure;

FIG. 1C shows a lateral schematic view of the electrical connection method of the light-emitting unit according to the first embodiment of the instant disclosure;

FIG. 1D shows a perspective schematic view of the first embodiment of the instant disclosure applied to the notebook;

FIG. 2 shows an antenna layout schematic view according to the second embodiment of the instant disclosure;

FIG. 3A shows a top schematic view according to the third embodiment of the instant disclosure;

FIG. 3B shows an antenna layout schematic view according to the third embodiment of the instant disclosure; and

FIG. 4 shows an antenna layout schematic view according to the fourth embodiment of the instant disclosure.

### DETAILED DESCRIPTION OF THE PREFERRED EMBODIMENTS

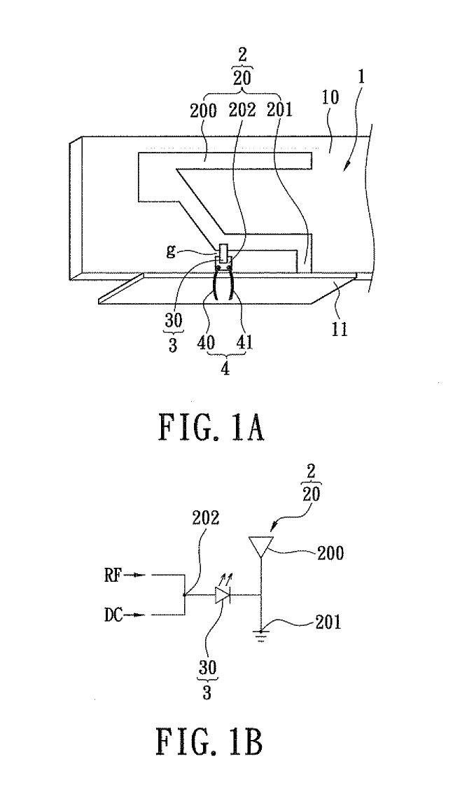

Referring to FIG. 1A and FIG. 1B, in which a top schematic view and an antenna layout schematic view according to the first embodiment of the instant disclosure are shown. The first embodiment of the instant disclosure provides an antenna module with antenna signal indicating function, including: a substrate unit 1, an antenna unit 2 and a light-emitting unit 3.

The substrate unit 1 has at least one insulating substrate 10 that can be made of any insulating materials. In addition, the antenna unit 2 has at least one antenna trace 20 formed on a surface of the insulating substrate 10. For example, the antenna trace 20 is formed on the top surface of the insulating substrate 10. Moreover, the antenna trace 20 has at least one antenna body 200, a grounding portion 201 electrically connected to the antenna body 200 and a feeding portion 202 electrically connected to the antenna body 200 for simultaneously receiving radio frequency (RF) signals and direct current (DC).

For example, the antenna trace 20 may be a conductive layer formed on the surface of the insulating substrate 10 by coating, printing, etching or any processing method. Of course, the antenna trace 20 may be a conductive layer adhered to the surface of the insulating substrate 10. In other words, the antenna trace 20 can be directly formed on the surface of insulating substrate 10, thus the antenna trace 20 and the insulating substrate 10 are combined together. Alternatively, the antenna trace 20 is adhered to the surface of the insulating substrate 10 by subsequent processing. However, the disclosure of placing the antenna trace 20 on the insulating substrate 10 is just an example and is not to limit the instant disclosure.

Furthermore, the substrate unit 1 has a grounding element 11 formed on a top surface of the insulating substrate 10, and the antenna trace 20 is formed on the top surface of the insulating substrate 10. For example, the grounding element 11 may be a grounding metal such as copper foil or copper sheet and the grounding element 11 can be extended downwards from the grounding portion 201 and along the top surface of the insulating substrate 10. In other words, the grounding portion 201 of the antenna trace 20 is electrically connected to ground through the grounding element 11 on the insulating substrate 10, and the feeding portion 202 of the antenna trace 20 is separated from the grounding element 11 with a predetermined distance, therefore, the feeding portion 202 has no contact with the grounding element 11.

Moreover, the light-emitting unit 3 has at least one light-emitting element 30 electrically connected between the antenna body 200 and the feeding portion 202, thus, the antenna body 200 and the light-emitting element 30 not only share the feeding portion 202, but also share the grounding portion 201. For example, the light-emitting element 30 may be an LED (Light Emitted Diode) package structure or an LED chip, thus the instant disclosure can use the packaged LED (covering LED chip with package resin to form the packaged LED) or the LED die without package resin to electrically connect between the antenna body 200 and the feeding portion 202.

In addition, the grounding portion 201 is connected with the antenna body 200, thus the grounding portion 201 is integrated with the antenna body 200. The feeding portion 202 and the antenna body 200 are separated with a predetermined distance which becomes a gap g. Therefore, the light-emitting element 30 can be disposed on the antenna body 200 or the feeding portion 202 to electrically connect between the antenna body 200 and the feeding portion 202. Alternatively, the light-emitting element 30 can traverse the gap g to electrically connect between the antenna body 200 and the feeding portion 202.

Furthermore, the antenna module further includes a signal-transmitting unit 4 that has a radio frequency signal transmission line 40 electrically connected to the feeding portion 202 and a direct current transmission line 41 electrically connected to the feeding portion 202. The signal-transmitting unit 4 can only provides one signal transmission line electrically connected to the feeding portion 202 and the signal transmission line can receive radio frequency (RF) signals and direct current (DC) at the same time, and another signal transmission line can be omitted.

In addition, regarding to the electrical connection method of the light-emitting element 30, the light-emitting element 30 can be electrically connected between the antenna body 200 and the feeding portion 202 by wire-bonding method or flip-chip method. For example, as shown in FIG. 1C, when both of the positive electrode P and the negative electrode N are disposed on the bottom surface of the light-emitting element 30, the positive electrode P and the negative electrode N of the light-emitting element 30 can be respectively and electrically connected to the antenna body 200 and the feeding portion 202 through two conductive bodies B such as two solder glue or two solder balls.

Referring to FIG. 1D, the antenna module of the instant disclosure can be installed in a top cover casing C1 of a laptop C (or be installed in a bottom cover casing C2 of the laptop C), and the light-emitting element 30 is exposed from the top cover casing C1. When the user turns on the antenna function of the notebook C for receiving the radio frequency signals, the antenna unit 2 and the light-emitting unit 3 can respectively receive the radio frequency signals and the direct current. Hence, it is easy for the user or bystander to know whether if the antenna unit 2 is in use or not according to the activities of the light-emitting unit 3.

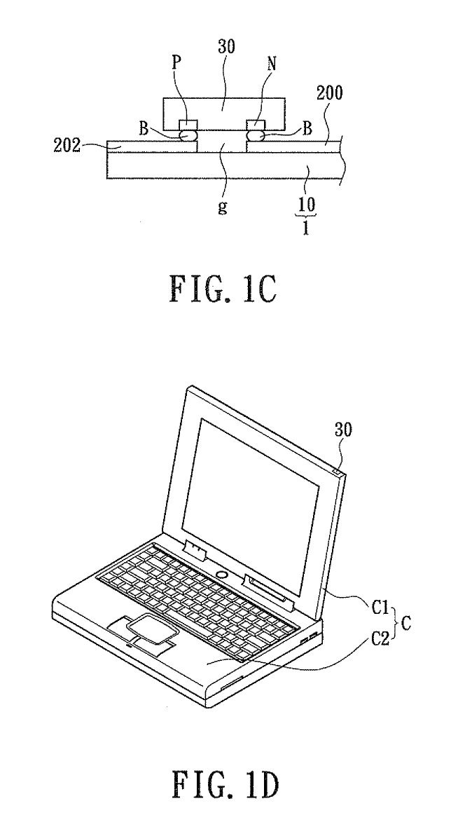

Referring to FIG. 2, in which an antenna layout schematic view according to the second embodiment of the instant disclosure is shown. The second embodiment of the instant disclosure provides an antenna module with antenna signal indicating function, including: a substrate unit (not shown), an antenna unit 2 and a light-emitting unit 3. Comparing FIG. 2 and FIG. 1B, the difference between the second embodiment and the first embodiment is that: in the second embodiment, the signal-transmitting unit 4 has a bias tee 43 electrically connected to the feeding portion 202, and the bias tee 43 has a radio frequency signal receiving side 430, a direct current receiving side 431 and an output side 432 electrically connected between the radio frequency signal receiving side 430 and the direct current receiving side 431. Therefore, because the radio frequency signal receiving side 430 is only connected to the output side 432, the radio frequency signal received by the radio frequency signal receiving side 430 can be directly transmitted to the feeding portion 202 of the antenna trace 20 through the output side 432. In addition, because the direct current receiving side 431 is only connected to the output side 432, the direct current received by the direct current receiving side 431 can be directly transmitted to the feeding portion 202 of the antenna trace 20 through the output side 432.

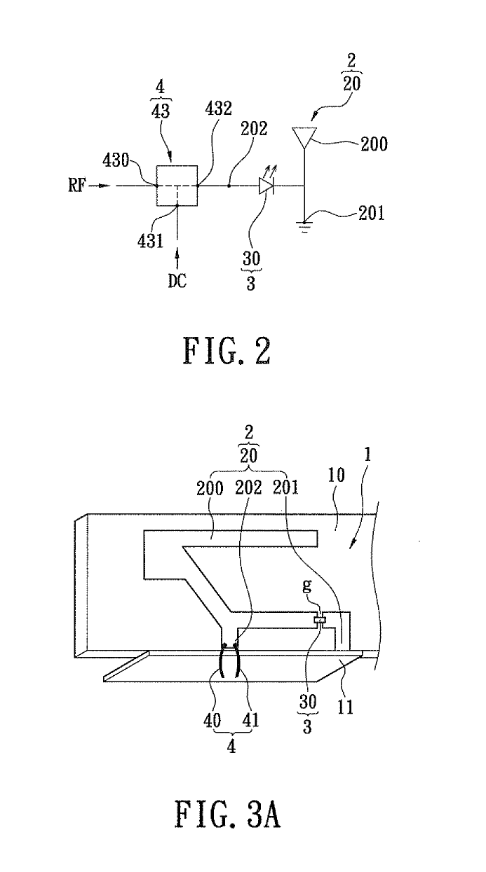

Referring to FIG. 3A and FIG. 3B, in which a top schematic view and an antenna layout schematic view according to the third embodiment of the instant disclosure are shown. The third embodiment of the instant disclosure provides an antenna module with antenna signal indicating function, including: a substrate unit 1, an antenna unit 2 and a light-emitting unit 3. There is a difference in the third embodiment comparing with the first embodiment which is the antenna trace 20 has at least one antenna body 200, a grounding portion 201 electrically connected to the antenna body 200 and a feeding portion 202 electrically connected to the antenna body 200 for simultaneously receiving radio frequency (RF) signals and direct current (DC). The light-emitting element 30 is electrically connected between the antenna body 200 and the grounding portion 201, thus the antenna body 200 and the light-emitting element 30 not only share the feeding portion 202, but also share the grounding portion 201.

In other words, the feeding portion 202 is connected with the antenna body 200, thus the feeding portion 202 is integrated with the antenna body 200. The grounding portion 201 and the antenna body 200 are separated with a predetermined distance which becomes a gap g. Therefore, the light-emitting element 30 can be disposed on the antenna body 200 or the grounding portion 201 to electrically connect between the antenna body 200 and the grounding portion 201. Alternatively, the light-emitting element 30 can traverse the gap g to electrically connect between the antenna body 200 and the grounding portion 201.

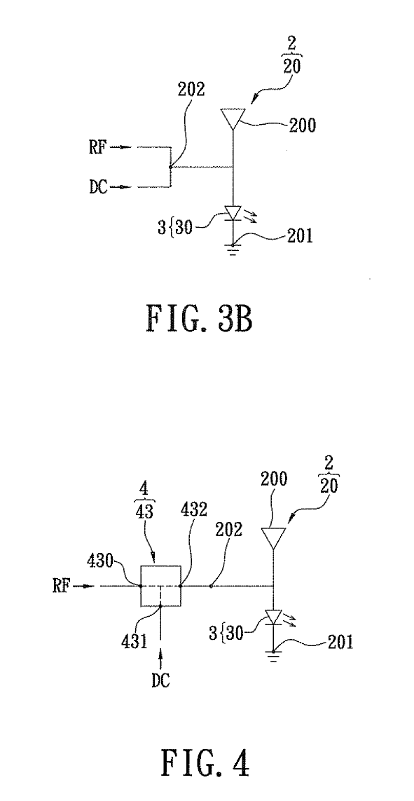

Referring to FIG. 4, in which an antenna layout schematic view according to the fourth embodiment of the instant disclosure is shown. The fourth embodiment of the instant disclosure provides an antenna module with antenna signal indicating function, including: a substrate unit (not shown), an antenna unit 2 and a light-emitting unit 3. Comparing FIG. 4 and FIG. 3B, There is a difference in the fourth embodiment comparing with the third embodiment which is the signal-transmitting unit 4 has a bias tee 43 electrically connected to the feeding portion 202, and the bias tee 43 has a radio frequency signal receiving side 430. A direct current receiving side 431 and an output side 432 electrically connect between the radio frequency signal receiving side 430 and the direct current receiving side 431. Therefore, because the radio frequency signal receiving side 430 is only connected to the output side 432, the radio frequency signal received by the radio frequency signal receiving side 430 can be directly transmitted to the feeding portion 202 of the antenna trace 20 through the output side 432. In addition, because the direct current receiving side 431 is only connected to the output side 432, the direct current received by the direct current receiving side 431 can be directly transmitted to the feeding portion 202 of the antenna trace 20 through the output side 432.

In conclusion, because the at least one light-emitting element can be integrated with the at least one antenna trace, the antenna module of the instant disclosure can simultaneously receive radio frequency signals and direct current. In other words, the at least one light-emitting element is considered in the antenna layout, thus the light-emitting element is electrically and disposed on the antenna trace to reduce the manufacturing cost of the antenna module. In addition, in practical use, when the user turns on the antenna function of the laptop for receiving the radio frequency signals, the antenna unit and the light-emitting unit can respectively receive the radio frequency signals and the direct current. Hence, it is easy for users or bystanders to know whether the antenna unit is in use or not according to the activities of the light-emitting unit.

The aforementioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. An antenna module with antenna signal indicating function, comprising:
a substrate unit having at least one insulating substrate;
an antenna unit having at least one antenna trace formed on a surface of the at least one insulating substrate, wherein the at least one antenna trace has at least one antenna body, a grounding portion electrically connected to the at least one antenna body and a feeding portion electrically connected to the at least one antenna body for simultaneously receiving radio frequency signals and direct current; and
a light-emitting unit having at least one light-emitting element electrically connected between the at least one antenna body and the feeding portion, thus the at least one antenna body and the at least one light-emitting element share the grounding portion.

2. The antenna module of claim 1, wherein the substrate unit has a grounding element formed on a top surface of the at least one insulating substrate, and the at least one antenna trace is formed on the top surface of the at least one insulating substrate.

3. The antenna module of claim 1, wherein the grounding portion is connected with the at least one antenna body, the feeding portion and the at least one antenna body are separated by a predetermined distance to generate a gap therebetween, and the at least one light-emitting element traverses the gap to electrically connect between the at least one antenna body and the feeding portion.

4. The antenna module of claim 1, further comprising: a signal-transmitting unit that has a radio frequency signal transmission line electrically connected to the feeding portion and a direct current transmission line electrically connected to the feeding portion.

5. The antenna module of claim 1, further comprising: a signal-transmitting unit electrically connected to the feeding portion.

6. The antenna module of claim 1, further comprising: a signal-transmitting unit that has a bias tee electrically connected to the feeding portion, wherein the bias tee has a radio frequency signal receiving side, a direct current receiving side and an output side electrically connected between the radio frequency signal receiving side and the direct current receiving side.

7. The antenna module of in claim 1, wherein the at least one light-emitting element is an LED package structure or an LED chip.

8. An antenna module with antenna signal indicating function, comprising:
a substrate unit having at least one insulating substrate;
an antenna unit having at least one antenna trace formed on a surface of the at least one insulating substrate, wherein the at least one antenna trace has at least one antenna body, a grounding portion electrically connected to the at least one antenna body and a feeding portion electrically connected to the at least one antenna body for simultaneously receiving radio frequency signals and direct current; and
a light-emitting unit having at least one light-emitting element electrically connected between the at least one antenna body and the grounding portion, thus the at least one antenna body and the at least one light-emitting element share the grounding portion.

9. The antenna module of claim 8, wherein the substrate unit has a grounding element formed on a top surface of the at least one insulating substrate, and the at least one antenna trace is formed on the top surface of the at least one insulating substrate.

10. The antenna module of claim 8, wherein the feeding portion is connected with the at least one antenna body, the grounding portion and the at least one antenna body are separated by a predetermined distance to generate a gap therebetween, and the at least one light-emitting element traverses the gap to electrically connect between the at least one antenna body and the grounding portion.

11. The antenna module of claim 8, further comprising: a signal-transmitting unit that has a radio frequency signal transmission line electrically connected to the feeding portion and a direct current transmission line electrically connected to the feeding portion.

12. The antenna module as of claim 8, further comprising: a signal-transmitting unit electrically connected to the feeding portion.

13. The antenna module as of claim 8, further comprising: a signal-transmitting unit that has a bias tee electrically connected to the feeding portion, wherein the bias tee has a radio frequency signal receiving side, a direct current receiving side and an output side electrically connected between the radio frequency signal receiving side and the direct current receiving side.

14. The antenna module as of claim 8, wherein the at least one light-emitting element is an LED package structure or an LED chip.
